(19) United States
(12) Patent Application Publication
(10) Pub. No.: US 2011/0110061 A1
(43) Pub. Date: May 12, 2011

(54) Circuit Board with Offset Via

(76) Inventor: Andrew KW Leung, Markham (CA)

(21) Appl. No.: 12/617,544

(22) Filed: Nov. 12, 2009

(51) Int. Cl. H05K 1/11; H05K 1/18; H05K 3/10

(52) U.S. Cl. 361/783; 174/262; 29/846

(57) ABSTRACT

Various circuit boards and methods of manufacturing the same are disclosed. In one aspect, a method of manufacturing is provided that includes forming a first interconnect layer of a circuit board. The first interconnect layer includes first and second conductor structures in spaced apart relation, a first via in ohmic contact with the first conductor structure and a second via in ohmic contact with the second conductor structure. A second interconnect layer is formed on the first interconnect layer. The second interconnect layer includes third and fourth conductor structures in spaced apart relation and offset laterally from the first and second conductor structures, a third via in ohmic contact with the third conductor structure and a fourth via in ohmic contact with the fourth conductor structure.

### BACKGROUND OF THE INVENTION

1. Field of the Invention

This invention relates generally to semiconductor processing, and more particularly to circuit boards with vias and to methods of making the same.

2. Description of the Related Art

Circuit boards of various types, including semiconductor chip package substrates and circuit cards, utilize conductor lines or traces to convey signals, power and ground from one point to another. Many conventional circuit board designs use multiple interconnect layers or levels. One layer is electrically linked to the next by way of conducting vias. The vias themselves are frequently formed on so-called via lands, which are shaped pads of conducting material. Many conventional circuit board vias typically have a circular footprint. One type of conventional via pad has a circular footprint and another type uses a rectangular footprint.

There is an on-going trend to squeeze more routing into circuit boards, particularly semiconductor chip package substrates. The need for greater routing complexity is caused by, among other things, increases in the number of input/outputs of ever more complex semiconductor die designs. It is not a trivial matter to insert more traces and vias into a circuit board layout. Indeed, the goal of increased routing must compete with design rules, which are put in place to ensure that manufacturing processes used to form the circuit board can do so reliably.

Conventional via and via lands are often vertically aligned from one interconnect layer to the next. Thus, one conventional mode for increasing packing density of routing traces involves shrinking vias and lands. However, any attempt to shrink a via size to accommodate additional trace routing needs to account for attendant increase in current densities in the via and the via land. If current densities exceed threshold levels, device failure can occur. Many conventional designs try to avoid the issue by essentially over designing the via hole laser drilling process. Holes are laser drilled with generous sizes. However, the large via hole sizes tend to prevent the placement of traces adjacent the vias in order to satisfy design rules.

The present invention is directed to overcoming or reducing the effects of one or more of the foregoing disadvantages.

### SUMMARY OF EMBODIMENTS OF THE INVENTION

In accordance with one aspect of an embodiment of the present invention, a method of manufacturing is provided that includes forming a first interconnect layer of a circuit board. The first interconnect layer includes first and second conductor structures in spaced apart relation, a first via in ohmic contact with the first conductor structure and a second via in ohmic contact with the second conductor structure. A second interconnect layer is formed on the first interconnect layer. The second interconnect layer includes third and fourth conductor structures in spaced apart relation and offset laterally from the first and second conductor structures, a third via is in ohmic contact with the third conductor structure and a fourth via is in ohmic contact with the fourth conductor structure.

In accordance with another aspect of an embodiment of the present invention, a method of conveying current in a circuit board is provided that includes nesting at least two conductor traces between first and second via lands in a first interconnect layer, the first and second via lands are offset laterally from third and fourth via lands in a second interconnect layer positioned on the first interconnect layer. A first current is conveyed through at the least two conductor traces.

In accordance with another aspect of an embodiment of the present invention, a circuit board is provided that includes a first interconnect layer that has first and second conductor structures in spaced apart relation, a first via in ohmic contact with the first conductor structure and a second via in ohmic contact with the second conductor structure. A second interconnect layer is on the first interconnect layer. The second interconnect layer includes third and fourth conductor structures in spaced apart relation and offset laterally from the first and second conductor structures, a third via in ohmic contact with the third conductor structure and a fourth via in ohmic contact with the fourth conductor structure.

In accordance with another aspect of an embodiment of the present invention, a method of manufacturing is provided that includes forming a first interconnect layer of a circuit board. The first interconnect layer includes a first conductor trace and a first conductor pad spaced apart from the first conductor trace. A second interconnect layer is formed on the first interconnect layer. The second interconnect layer includes a second conductor pad and a second conductor trace. The second conductor trace is offset laterally from the first conductor trace and offsets the second conductor pad laterally from the first conductor pad.

### BRIEF DESCRIPTION OF THE DRAWINGS

The foregoing and other advantages of the invention will become apparent upon reading the following detailed description and upon reference to the drawings in which:

FIG. 1 is a pictorial view of an exemplary conventional a semiconductor chip device that includes a semiconductor chip mounted on a circuit board;

FIG. 2 is a sectional view of FIG. 1 taken at section 2-2;

FIG. 3 is a sectional view of a small portion of an exemplary embodiment of a semiconductor chip device that includes a semiconductor chip mounted to a circuit board;

FIG. 4 is a portion of FIG. 3 shown at greater magnification;

FIG. 5 is a sectional view of a portion of the circuit board shown in FIG. 3 depicting exemplary processing steps to establish conductor pads and traces;

FIG. 6 is a sectional view like FIG. 5, but depicting additional exemplary processing steps to establish conductor pads and traces;

FIG. 7 is a sectional view like FIG. 6, but depicting formation of a build-up layer;

FIG. 8 is a sectional view like FIG. 7, but depicting laser drilling of via openings in the build-up layer;

FIG. 9 is an overhead view of the laser drilling process;

FIG. 10 is a sectional view like FIG. 9, but depicting exemplary via formation; and

FIG. 11 is a sectional view like FIG. 10, but depicting presolder attachment.

### DETAILED DESCRIPTION OF SPECIFIC EMBODIMENTS

Various embodiments of a printed circuit board, such as a semiconductor chip package carrier substrate, are described herein. One example includes multiple interconnect layers with at least one that has adjacent vias and via lands offset laterally to accommodate nested conductor traces. Additional details will now be described.

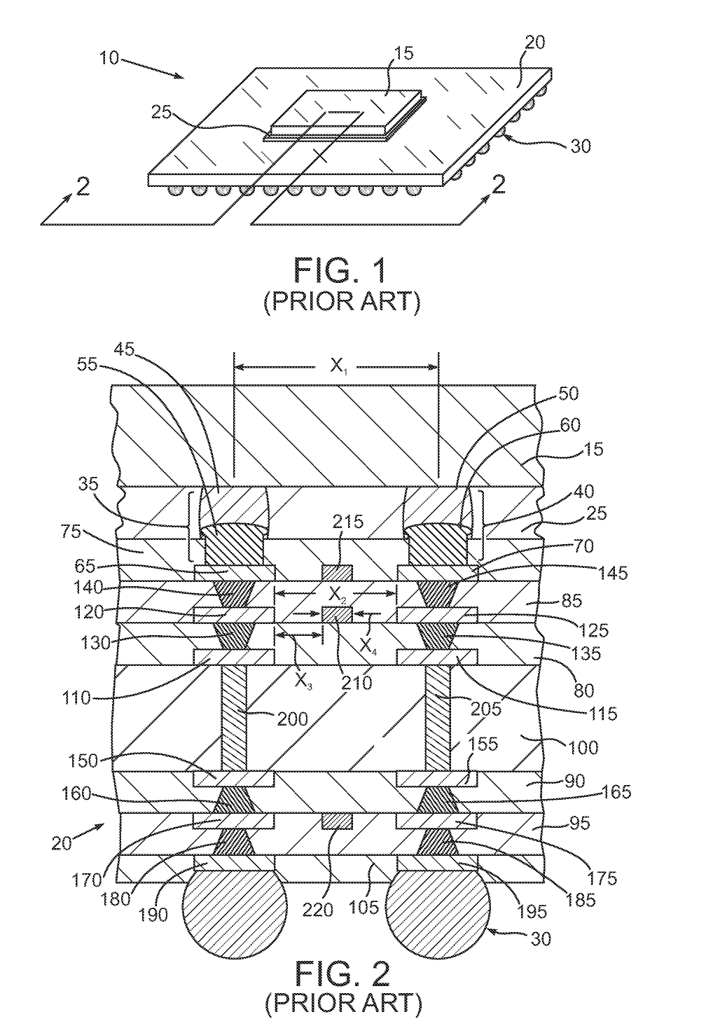

In the drawings described below, reference numerals are generally repeated where identical elements appear in more than one figure. Turning now to the drawings, and in particular to FIG. 1, therein is shown a pictorial view of an exemplary conventional semiconductor chip package 10 that includes a semiconductor chip 15 mounted on a package substrate 20. An underfill material layer 25 is positioned between the semiconductor chip 15 and the package substrate 20. The package substrate 20 is provided with a number of conductor traces and vias and other structures in order to provide power, ground and signals transfers between the semiconductor chip 15 and some other circuit device that is not shown. To facilitate those transfers, the package substrate 20 includes input/outputs in the form of a ball grid array 30 consisting of plural solder balls.

Attention is now turned to FIG. 2, which is a sectional view of FIG. 1 taken at section 2-2. Note that section 2-2 only encompasses a rather small portion of the semiconductor chip 15 and the package substrate 20. As shown, the semiconductor chip 15 is flip-chip mounted to the circuit board 20 and electrically connected thereto by way of plural solder joints 35 and 40. While only two solder joints 35 and 40 are depicted, there may be scores, hundreds or even thousands of such joints depending upon the size of complexity of the semiconductor chip 15 and the package substrate 20. The solder joints 35 and 40 consist of respective solder bumps 45 and 50 that are coupled to the semiconductor chip 15 and presolders 55 and 60 that are metallurgically bonded to respective conductor pads 65 and 70 of the package substrate 20. The presolders 55 and 60 are separated laterally by a solder mask 75. The solder bumps 45 and 50 are metallurgically coupled to the presolders 55 and 60 by way of a reflow and bump collapse process.

The package substrate 20 is a 2-2-2 build-up design. In this regard, interconnect or build-up layers 80 and 85 and 90 and 95 are formed on opposite sides of a core 100. The build-up layers 80, 85, 90 and 95, the core 100, the solder mask 75 and another solder mask 105 formed on the build-up layer 95 make up an interconnect system for the package substrate 20. The following discussion of the various conductor structures in FIG. 2 will be illustrative of other conductor structures in the conventional package substrate 20. The build-up layer 80 includes respective conductor structures or pads 110 and 115 that are interconnected with another set of conductor structures or pads 120 and 125 in the build-up layer 85 by way of respective vias 130 and 135 formed in the build-up layer 80. Similarly, the conductor pads 120 and 125 in the build-up layer 85 are electrically connected to the overlying conductor pads 65 and 70 in the solder mask 75 by way of respective vias 140 and 145. Electrical pathways through the build-up layers 90 and 95 and the solder mask 105 are similarly provided by way of conductor pads 150 and 155 and vias 160 and 165 in the build-up layer 90, conductor pads 170 and 175 and corresponding vias 180 and 185 in the build-up layer 85 and ball pads 190 and 195 in the solder mask 105 that are connected to the vias 180 and 185. The solder balls 30 are metallurgically bonded to the ball pads 190 and 195. Electrical pathways through the core 100 are provided by way of plated thru holes 200 and 205.

The solder joints 35 and 40 are fabricated with a bump pitch x₁, the size of which is dependent upon a variety of factors, such as the size of the semiconductor chip 15, the number of input/output pathways required for the semiconductor chip 15 and other considerations. The interconnect structures that are connected to the solder joint 35, such as the conductor pad 65, the via 140, the conductor pad 120, the via 130 and the conductor pad 110 are all vertically aligned with the solder joint 35 and have a circular footprint when viewed from above or below. The same is true for the various interconnect structures that are connected to the solder joint 40, such as the conductor pad 70, the via 125, the conductor pad 145, the via 135 and the conductor pad 115.

The build up layer 85 includes a conductor trace 210 that is positioned between the conductor pads 120 and 125 and the build up layer 75 includes a conductor trace 215 that is positioned between conductor pads 65 and 70. The conductor traces 210 and 215 provide routing of power, ground or signals. A typical conventional design rule for the conductor pads and vias is such that there is a minimum spacing x₂ between the conductor pads 120 and 125 in the build up layer 85. This minimum spacing x₂ is some combination of the gap x₃ between the conductor trace 210 and the conductor pad 120, the corresponding gap between the conductor trace 210 and the conductor pad 125, and the width x₄ of the conductor trace 210. In accordance with this conventional design, and due to the bump pitch x₁ and the required minimum spacing x₂, only a single conductor trace 210 may be positioned in between the conductor pads 120 and 125 in the build up layer 85.

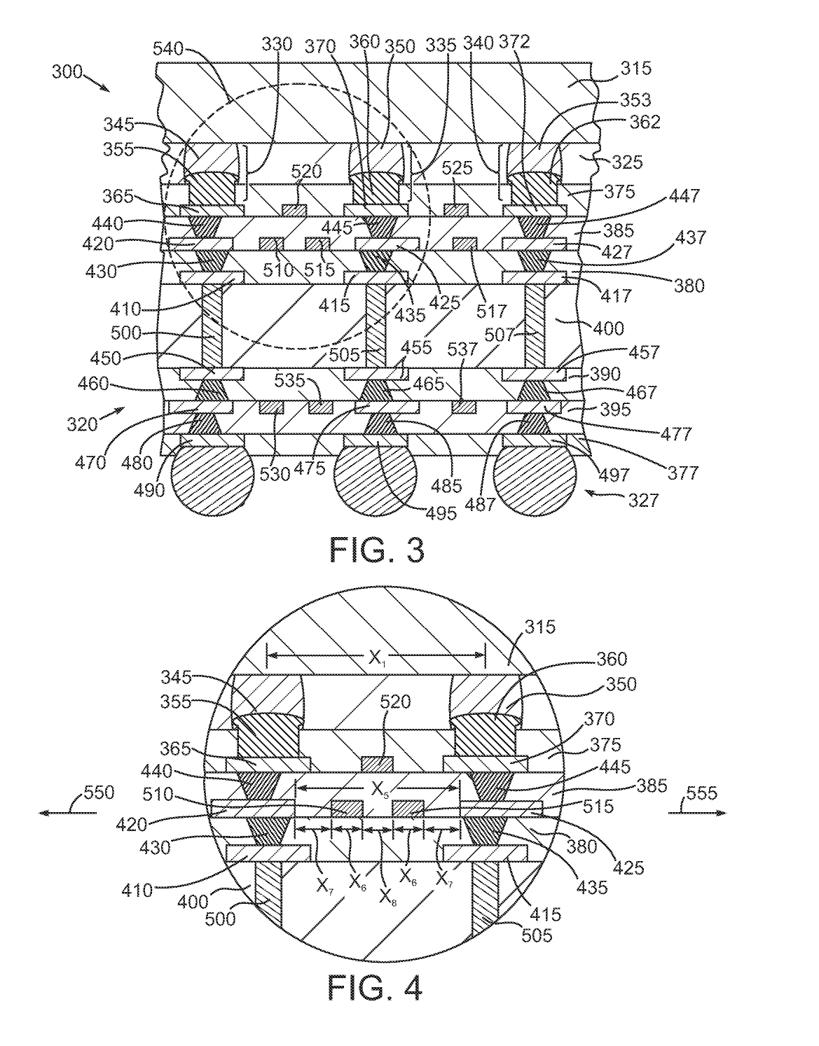

FIG. 3 is a sectional view of a small portion of an exemplary embodiment of a semiconductor chip device 300 that includes a semiconductor chip 315 mounted to a circuit board 320. An underfill material layer 325 is disposed between the semiconductor chip 315 and the circuit board 320 to lessen the effects of differential CTE. The semiconductor chip 315 may be any of a myriad of different types of circuit devices used in electronics, such as, for example, microprocessors, graphics processors, combined microprocessor/graphics processors, application specific integrated circuits, memory devices or the like, and may be single or multi-core or even stacked with additional dice. The semiconductor chip 315 may be constructed of bulk semiconductor, such as silicon or germanium, or semiconductor on insulator materials, such as silicon-on-insulator materials. The semiconductor chip 315 may be flip-chip mounted to the circuit board 320 and electrically connected thereto by solder joints or other structures. Interconnect schemes other than flip-chip solder joints may be used.

The circuit board 320 may be a semiconductor chip package substrate, a circuit card, or virtually any other type of printed circuit board. Although a monolithic structure could be used for the circuit board 320, a more typical configuration will utilize a build-up design. In this regard, the circuit board 320 may consist of a central core upon which one or more build-up layers are formed and below which an additional one or more build-up layers are formed. The core itself may consist of a stack of one or more layers. One example of such an arrangement may be a 2-2-2 arrangement where a single-layer core is laminated between two sets of two build-up layers. If implemented as a semiconductor chip package substrate, the number of layers in the circuit board 320 can vary from four to sixteen or more, although less than four may be used. So-called “coreless” designs may be used as well. The layers of the circuit board 320 may consist of an insulating material, such as various well-known epoxies or other polymers, interspersed with metal interconnects. A multi-layer configuration other than build-up could be used. Optionally, the circuit board 320 may be composed of well-known ceramics or other materials suitable for package substrates or other printed circuit boards.

The circuit board 320 is provided with a number of conductor traces and vias and other structures in order to provide power, ground and signals transfers between the semiconductor chip 315 and another circuit device that is not shown. To facilitate those transfers, the circuit board 320 may be provided with input/outputs in the form of a pin grid array, a ball grid array, a land grid array or other type of interconnect scheme. In this illustrative embodiment, the circuit board 320 is provided with a ball grid array consisting of plural solder balls 327.

The semiconductor chip 315 may be flip-chip mounted to the circuit board 320 and electrically interconnected thereto by solder joints, conductive pillars or other structures. In this illustrative embodiment, three solder structures or joints 330, 335 and 340 are depicted. While only three solder joints 330, 335 and 340 are depicted, there may be scores, hundreds or even thousands of such joints depending upon the size of complexity of the semiconductor chip 315 and the circuit board 320. The solder joints 330, 335 and 340 may consist of respective solder bumps 345, 350 and 353 that are coupled to the semiconductor chip 315 and presolders 355, 360 and 362 that are metallurgically bonded to respective conductor pads 365, 370 and 372 of the circuit board 320. The solder bumps 345, 350 and 353 are metallurgically coupled to the presolders 355, 360 and 362 by way of a reflow and bump collapse process.

The solder bumps 345, 350 and 353, and the solder balls 327 may be composed of various lead-based or lead-free solders. An exemplary lead-based solder may have a composition at or near eutectic proportions, such as about 63% Sn and 37% Pb. Lead-free examples include tin-silver (about 97.3% Sn 2.7% Ag), tin-copper (about 99% Sn 1% Cu), tin-silver-copper (about 96.5% Sn 3% Ag 0.5% Cu) or the like. The presolders 355, 360 and 362 may be composed of the same types of materials. Optionally, the presolders 355, 360 and 362 may be eliminated in favor of a single solder structure or a solder plus a conducting pillar arrangement. The underfill material layer 325 may be, for example, an epoxy resin mixed with silica fillers and phenol resins, and deposited before or after the re-flow process to establish the solder joints 330, 335 and 340. The presolders 355, 360 and 362 and the conductor pads 365, 370 and 372 are surrounded laterally by a solder mask 375 that is patterned lithographically, by laser ablation or the like, to form plural openings in order to accommodate the various presolders, for example, the presolders 355, 360 and 362. Another solder mask 377 is positioned on the opposite side of the circuit board 320 to facilitate the attachment of the solder balls 327. The solder masks 375 and 377 may be fabricated from a variety of materials suitable for solder mask fabrication, such as, for example, PSR-4000 AUS703 manufactured by Taiyo Ink Mfg. Co., Ltd. or SR7000 manufactured by Hitachi Chemical Co., Ltd.

In this illustrative embodiment, the circuit board 320 is implemented as a semiconductor chip package with a 2-2-2 build-up design. In this regard, interconnect or build-up layers 380 and 385 and 390 and 395 are formed on opposite sides of a core 400. The core 400 may be monolithic or a laminate or two or more layers as desired. The core 400 and the build-up layers 380, 385, 390 and 395 may be composed of well-known polymeric materials, such as, GX13 supplied by Ajinomoto, Ltd. The build-up layers 380, 385, 390 and 395, the core 400, and the solder masks 375 and 377 make up an interconnect system for the circuit board 320. The following discussion of the various conductor structures in FIG. 3 will be illustrative of other conductor structures in the circuit board 320. The build-up layer 380 may include respective conductor structures or pads 410, 415 and 417 that are interconnected or in ohmic contact with another set of conductor structures or pads 420, 425 and 427 in the build-up layer 385 by way of respective vias 430, 435 and 437 formed in the build-up layer 380. Similarly, the conductor pads 420, 425 and 427 in the build-up layer 385 may be electrically connected to the overlying conductor pads 365, 370 and 372 in the solder mask 375 by way of respective vias 440, 445 and 447. Electrical pathways through the build-up layers 390 and 395 and the solder mask 377 may be similarly provided by way of conductor pads 450, 455 and 457 and vias 460, 465 and 467 in the build-up layer 390, conductor pads 470, 475 and 477 and corresponding vias 480, 485 and 487 in the build-up layer 395 and ball pads 490, 495 and 497 in the solder mask 377 that are connected to the vias 480, 485 and 487. The solder balls 327 are metallurgically bonded to the ball pads 490, 495 and 497. Electrical pathways through the core 400 may be provided by way of thru-vias 500, 505 and 507, which may be plated thru holes or other types of conductors.

Still referring to FIG. 3, the buildup layer 385 may include plural conductor traces, three of which are visible and labeled 510, 515 and 517, respectively. The buildup layer 375 may include plural conductor traces 520 and 525 and the buildup layer 395 may include conductor traces 530, 535 and 537. The conductor traces 510 and 515 may be nested between the conductor pads 420 and 425 and the conductor traces 530 and 535 may be nested between the conductor pads 470 and 475. As described in more detail below, the advantageous nesting of multiple traces 510 and 515 between the conductor pads 420 and 425 and the traces 530 and 535 between the conductor pads 470 and 475 provides for more complex and flexible routing of power, ground and/or signals in the circuit board 320 than might otherwise be possible using conventional designs where design rules and conventional interconnect placement might prevent the nesting of such multiple traces.

The portion of FIG. 3 circumscribed by the dashed circle 540 will be shown at greater magnification in FIG. 4. Attention is now turned to FIG. 4. A technical goal of this illustrative embodiment is to enable the nesting of the two traces 510 and 515 between the conductor pads 420 and 425 and vias 440 and 445 without having to increase the bump pitch between the solder joints 330 and 335 beyond the value x₁. To accomplish this nesting, the conductor pad 420 is offset laterally in the direction of the arrow 550 and the conductor pad 425 is correspondingly, but oppositely, offset laterally in the direction of the arrow 555. The vias 440 and 445 are similarly offset in the directions of the arrows 550 and 555 to maintain an approximation of a vertical alignment with their respective underlying conductor pads 420 and 425. The vias 430 and 435 in the build up layer 380 may be substantially vertically aligned with their respective conductor pads 410 and 415 and the underlying plated through holes 500 and 505 in the core 400. Similarly, the solder bump 345, the presolder 355 and the conductor pad 365 may be vertically aligned and the solder bump 350, the presolder 360 and the conductor pad 370 may be vertically aligned. The conductor pads 420 and 425 may be laterally offset in the respective directions 550 and 555 so that a total gap x₅ exists therebetween. The total gap x₅ may be the sum of the gaps x₇ between the conductor pad 420 and the trace 510 and the trace 515 and the conductor pad 425, the combined lateral dimensions x₆ of the traces 510 and 515 and the gap x₈ between the traces 510 and 515. If desired, the quantities x₆, x₇ and x₈ may be equal or unequal. In this way, some minimum design rule spacing between a trace and a pad such as the spacing x₇ and some minimum inter trace spacing, such as x₈, may be maintained while providing nested traces without expanding the bump pitch x₁. The conductor trace 520 may be positioned between the conductor pads 365 and 370 in the conventional manner. Optionally, multiple traces may be nested on multiple build up layers, such as not only build up layer 385 but also in the solder mask 375, if desired. Thus, more complex routing to facilitate greater complexity of input/outputs from the semiconductor chip 315 may be provided without expanding the bump pitch beyond x₁.

Referring again to FIG. 3, in order to facilitate the lateral offset of the pads 420 and 425 and the vias 440 and 445, it may not be possible to have nested traces between the next adjacent set of pads and vias such as the pad 427 and the via 447. It may only be possible to have a single trace 517 positioned between the pads 425 and 427 and the vias 445 and 447. However, it is anticipated that the nesting of two or more traces between pairs of pads and vias using the lateral offset technique described herein may be used in multiple locations within the circuit board 320. It should also be understood that the offsetting of the pads and vias may be asymmetric. For example, it may possible to only offset the conductor pad 420 and the via 440 laterally and still accommodate nested traces.

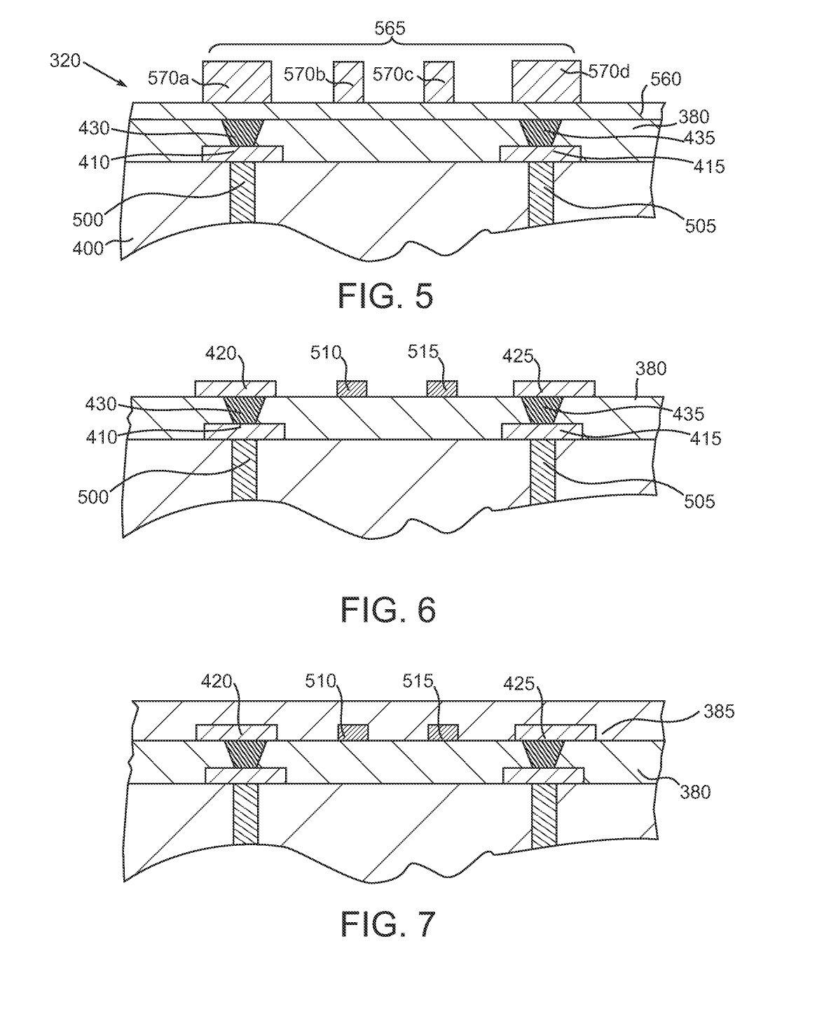

An exemplary method for fabricating the offset conductor pads 420 and 425 and vias 440 and 445 and other structures of the interconnect scheme may be understood by referring now to FIGS. 5, 6, 7 and 8 and initially to FIG. 5. FIG. 5 is a sectional view like FIG. 3, but for simplicity of illustration only depicts an upper portion of the core 400 and the thru-vias 500 and 505 of the circuit board 320. In addition, the overlying semiconductor chip 315 depicted in FIGS. 3 and 4 is not attached at this point and thus not depicted. The build-up layer 380 including the conductor pads 410 and 415 and the vias 430 and 435 have already been constructed. At this point, a conductor layer 560 may be applied to the build-up layer 380. Through subsequent processing, the conductor layer 560 will be transformed into pairs of conductor pads and signal traces as described in more detail below. The conductor layer 560 may be fabricated from a variety of conductor materials, such as aluminum, copper, silver, gold, titanium, refractory metals, refractory metal compounds, alloys of these or the like. In lieu of a unitary structure, the conductor layer 560 may consist of a laminate of plural metal layers, such as a titanium layer followed by a nickel-vanadium layer followed by a copper layer. In another embodiment, a titanium layer may be covered with a copper layer followed by a top coating of nickel. However, the skilled artisan will appreciate that a great variety of conducting materials may be used for the conductor layer 560. Various well-known techniques for applying metallic materials may be used, such as physical vapor deposition, chemical vapor deposition, plating or the like. In an exemplary embodiment, the conductor layer 560 may be composed of copper and deposited by well-known plating processes.

At this stage, a mask 565 may be formed on the conductor layer 560 and patterned lithographically into plural portions 570a, 570b, 570c and 570d. The mask portions 570a and 570d are offset laterally from the vias 430 and 435, respectively so that the later-formed conductor pads 420 and 425 (see FIGS. 3 and 4) will have the desired lateral offset. The portions 570a, 570b, 570c and 570d are patterned to have the desired footprints of the later formed conductor structures. For example, if the conductor pads 420 and 425 shown in FIGS. 3 and 4 are slated to have circular or oval footprints, then the mask portions 570b and 570c are lithographically patterned as circles or ovals. It may be necessary, depending upon the limitations associated with the lithographic patterning of the mask 565, to approximate curved shapes by way of a series of interconnecting polygons, which are generally more readily available for lithography processing than strictly rounded shapes.

Referring now to FIG. 6, following the formation of the mask 565, the conductor layer 560 is subjected to an etch process to remove those exposed portions of the conductor layer 560. Following the etch process, the mask 565 may be removed by ashing, solvent stripping or combinations of the two. Following the removal of the mask 565 shown in FIG. 5 from the buildup layer 380, the conductor pads 420 and 425 as well as the traces 510 and 515 remain. The conductor pad 420 is offset laterally from the via 430, the conductor pad 410 and the thru-via 500. The same is true, albeit in the opposite direction, for the conductor pad 425 relative to the via 435, the conductor pad 415 and the thru-via 505.

Attention is now turned to FIG. 7. Following the patterning of the pads 420 and 425 and the traces 510 and 515, the build-up layer 385 may be formed on the buildup layer 380. An insulating material of the type(s) described elsewhere herein may be deposited by spin coating or other techniques and cured by heating or otherwise. At this stage, the build-up layer 385 covers the pads 420 and 425 and the traces 510 and 515.

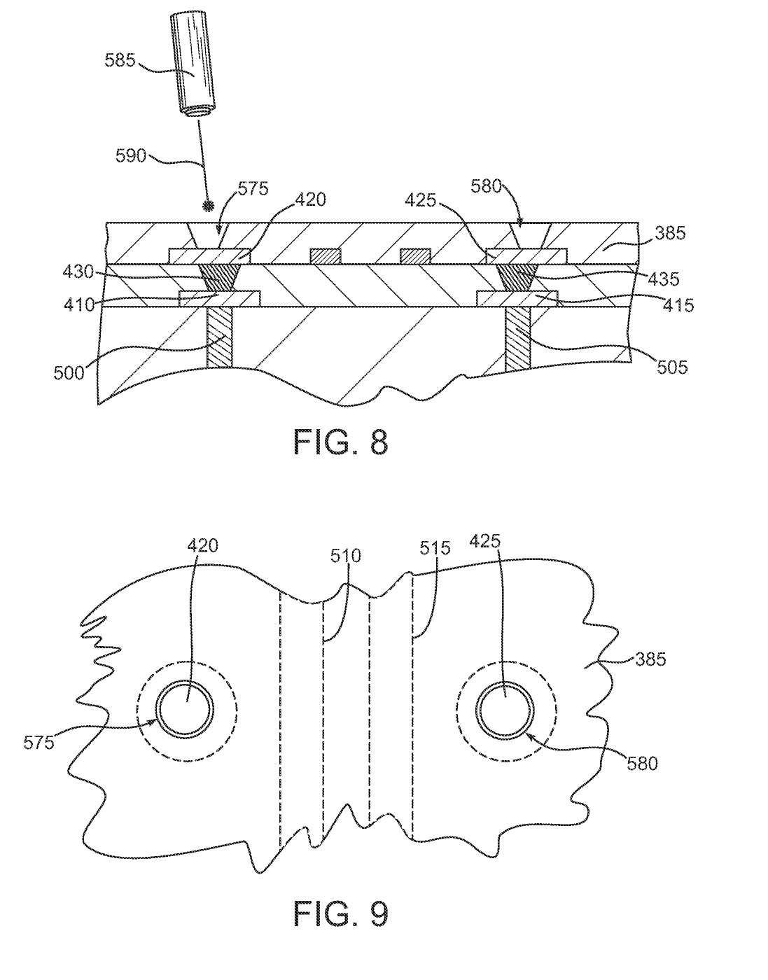

The process of forming openings in the build-up layer 385 to accommodate the subsequently formed vias will be described now in conjunction with FIG. 8. In an exemplary embodiment, the openings 575 and 580 may be formed over the conductor pads 420 and 425 by laser cutting. A laser 585 may deliver the laser radiation 590 in pulses or as a continuous beam. The wavelength and spot size of the laser radiation 590 are selected to effectively ablate the build-up layer material layer 385 while producing the openings 575 and 580 with desired sizes and footprints. For example, radiation 590 in the ultraviolet range and with a spot size in the 2 to 5 micron range could be used. It is necessary for the openings 575 and 580 to be drilled completely to the underlying pads 420 and 425, but some care should be exercised to ensure that the cutting process does not remove excessive material from the pads 420 and 425. The opening 575 is offset laterally from the conductor pad 420, the via 430, the conductor pad 410 and the thru-via 500. The opening 580 is similarly offset laterally from the conductor pad 425, the via 435, the conductor pad 415 and the thru-via 505 in the opposite direction.

An overhead view of the buildup layer 385 and the formed openings 575 and 580 is depicted in FIG. 9. A portion of the conductor pad 420 exposed by the opening 575 is visible, but the outer perimeter is covered and thus shown in phantom. The same is true for the conductor pad 425 and the opening 580. The nested conductor traces 510 and 515 remain covered and are thus similarly shown in phantom.

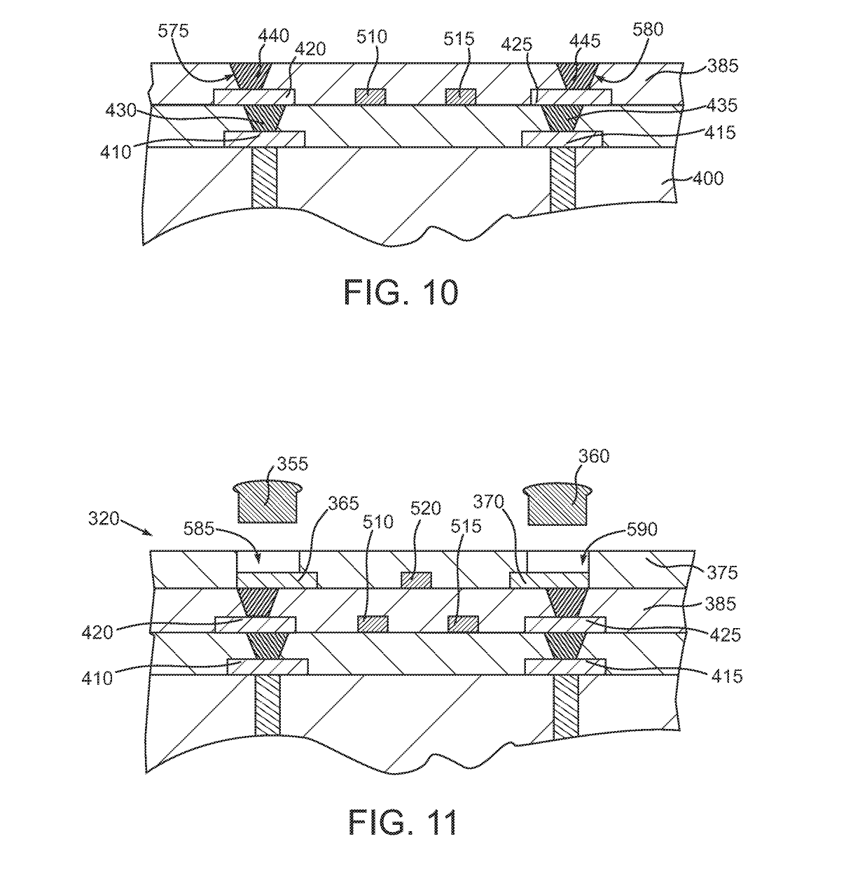

Referring now to FIG. 10, following the formation of the openings 575 and 580, the vias 440 and 445 may be formed therein. The vias 440 and 445 may be composed of a variety of conductor materials, such as aluminum, copper, silver, gold, titanium, refractory metals, refractory metal compounds, alloys of these or the like. In lieu of a unitary structure, the vias 440 and 445 may consist of a laminate of plural metal layers, such as a titanium layer followed by a nickel-vanadium layer followed by a copper layer. In another embodiment, a titanium layer may be covered with a copper layer followed by a top coating of nickel. However, the skilled artisan will appreciate that a great variety of conducting materials may be used for the vias 440 and 445. Various well-known techniques for applying metallic materials may be used, such as physical vapor deposition, chemical vapor deposition, plating or the like. In an exemplary embodiment, the vias may be formed by copper plating performed in two stages. The first stage involves the application of a relatively thin layer of copper in the openings 575 and 580. In a second stage a bulk plating process is performed to fill in the vias 440 and 445.

The processes described herein for establishing the build-up layer 385 on the buildup layer 380, including the conductor pads 420 and 425, the traces 510 and 515 and the vias 440 and 445, may also be used to establish the build-up layer 380 including the conductor pads 410 and 415 and the vias 430 and 435 thereof. The same is true for any of the other layers on the opposite side of the core 400.

Referring now to FIG. 11, the build-up layer consisting of the solder mask 375, the conductor pads 365 and 370 and the conductor trace 520 may be formed on the build-up layer 385 by well-known material deposition and patterning techniques. For example, the conductor pads 365 and 370 and the conductor trace 520 may be fabricated using the same general conductor deposition and patterning techniques used to form the conductor pads 410 and 415 and 420 and 425 and the conductor traces 510 and 515 as described elsewhere herein. The solder mask 375 may be deposited using well-known solder mask deposition techniques, such as spin coating or other deposition techniques as desired. Suitable openings 585 and 590 may be formed in the solder mask 375 by well-known lithographic patterning techniques. The openings 585 and 590 are advantageously positioned over the conductor pads 365 and 370. At this point, the presolders 355 and 360 may be positioned in the openings 585 and 590 and coined as shown. For example, a solder paste may be applied by stencil or the like. A reflow may be performed at this point to bond the presolders 355 and 360 to the underlying conductor pads 365 and 370.

Following the application of the presolders 355 and 360, the semiconductor chip 315 depicted in FIGS. 1 and 2 may be positioned on the circuit board 320 and mounted to the presolders 355 and 360. A reflow process performed to create the solder joints 330 and 335 depicted in FIG. 2. The temperature and duration of the reflow will depend upon the types of solders and the geometry of the circuit board 320 and the semiconductor chip 315.

It should be understood that the processes described herein could be performed on a discrete circuit board or en masse on a strip or other aggregation of circuit boards. If done on en masse, the individual circuit boards may be singulated at some stage by sawing or other techniques.

Any of the exemplary embodiments disclosed herein may be embodied in instructions disposed in a computer readable medium, such as, for example, semiconductor, magnetic disk, optical disk or other storage medium or as a computer data signal. The instructions or software may be capable of synthesizing and/or simulating the circuit structures disclosed herein. In an exemplary embodiment, an electronic design automation program, such as Cadence APD, Encore or the like, may be used to synthesize the disclosed circuit structures. The resulting code may be used to fabricate the disclosed circuit structures.

While the invention may be susceptible to various modifications and alternative forms, specific embodiments have been shown by way of example in the drawings and have been described in detail herein. However, it should be understood that the invention is not intended to be limited to the particular forms disclosed. Rather, the invention is to cover all modifications, equivalents and alternatives falling within the spirit and scope of the invention as defined by the following appended claims.

What is claimed is:

1. A method of manufacturing, comprising:
forming a first interconnect layer of a circuit board, the first interconnect layer including first and second conductor structures in spaced apart relation, a first via in ohmic contact with the first conductor structure and a second via in ohmic contact with the second conductor structure; and
forming a second interconnect layer on the first interconnect layer, the second interconnect layer including third and fourth conductor structures in spaced apart relation and offset laterally from the first and second conductor structures.

2. The method of claim 1, wherein the second interconnect layer is formed with a third via in ohmic contact with the third conductor structure and a fourth via in ohmic contact with the fourth conductor structure.

3. The method of claim 1, wherein the third and fourth vias are offset laterally from the first and second vias.

4. The method of claim 1, comprising forming at least two conductor traces in the second interconnect layer between the third and fourth conductor structures.

5. The method of claim 4, comprising forming a conductor trace in the first interconnect layer between the first and second conductor structures.

6. The method of claim 1, comprising coupling a semiconductor chip to the circuit board.

7. The method of claim 1, comprising forming the third and fourth conductor structures using instructions stored in a computer readable medium.

8. The method of claim 1, comprising coupling plural solder balls to the circuit board.

9. A method of conveying current in a circuit board, comprising:
nesting at least two conductor traces between first and second via lands in a first interconnect layer, the first and second via lands being offset laterally from third and fourth via lands in a second interconnect layer positioned on the first interconnect layer; and
conveying a first current through the at least two conductor traces.

10. The method of claim 9, wherein the first current comprises electrical signals.

11. The method of claim 9, wherein the first interconnect layer comprises a third via in ohmic contact with the first via land and a fourth via in ohmic contact with the second via land.

12. The method of claim 9, comprising conveying a second current through the first via land, the first via and the third via land.

13. The method of claim 9, comprising conveying a third current through a conductor trace positioned between the third and fourth via lands.

14. The method of claim 9, wherein the circuit board comprises a semiconductor chip, the method comprising using the at least two conductor traces via to convey the first current between the semiconductor chip and the circuit board.

15. A circuit board, comprising:
a first interconnect layer including first and second conductor structures in spaced apart relation, a first via in ohmic contact with the first conductor structure and a second via in ohmic contact with the second conductor structure; and
a second interconnect layer on the first interconnect layer, the second interconnect layer including third and fourth conductor structures in spaced apart relation and offset laterally from the first and second conductor structures, a third via in ohmic contact with the third conductor structure and a fourth via in ohmic contact with the fourth conductor structure.

16. The circuit board of claim 15, wherein the third and fourth vias are offset laterally from the first and second vias.

17. The circuit board of claim 15, comprising a conductor trace positioned between the first and second conductor structure.

18. The circuit board of claim 15, wherein the first interconnect layer comprises a build-up layer.

19. The circuit board of claim 15, comprising a semiconductor chip coupled to the circuit board.

20. The circuit board of claim 15, wherein the first interconnect layer comprises a solder mask.

21. The circuit board of claim 15, comprising plural solder balls coupled to the circuit board.

22. A method of manufacturing, comprising:
forming a first interconnect layer of a circuit board, the first interconnect layer including first conductor trace and a first conductor pad spaced apart from the first conductor trace; and
forming a second interconnect layer on the first interconnect layer, the second interconnect layer including a second conductor pad and a second conductor trace, the second conductor trace offset laterally from the first conductor trace and offsetting the second conductor pad laterally from the first conductor pad.

23. The method of claim 22, comprising forming a first via in ohmic contact with the first conductor pad and a second via in ohmic contact with the second conductor pad.
